(19) United States
(12) Patent Application Publication
(10) Pub. No.: US 2008/0032475 A1
(43) Pub. Date: Feb. 7, 2008

(54) MEMORY CELL SYSTEM WITH GRADIENT CHARGE ISOLATION

(75) Inventors: Amol Ramesh Joshi, Sunnyvale, CA (US); Meng Ding, Sunnyvale, CA (US); Takashi Orimoto, Sunnyvale, CA (US)

Correspondence Address: LAW OFFICES OF MIKIO ISHIMARU, 333 W. EL CAMINO REAL, SUITE 330, SUNNYVALE, CA, 94087, US

(73) Assignees: SPANSION LLC, Sunnyvale, CA (US); ADVANCED MICRO DEVICES, INC., Sunnyvale, CA (US)

(21) Appl. No.: 11/462,009

(22) Filed: Aug. 2, 2006

(51) Int. Cl. H01L 21/336

(52) U.S. Cl. 438/257

(57) ABSTRACT

A memory cell system is provided including forming a first insulator layer over a semiconductor substrate, forming a charge trap layer having a gradient of a silicon above and below the charge trap layer over the first insulator layer, and forming a second insulator layer over the charge trap layer.

### CROSS-REFERENCE TO RELATED APPLICATIONS

This application claims the benefit of U.S. patent application Ser. No. 11/277,008 filed Mar. 20, 2006.

This application contains subject matter related to a co-pending U.S. Patent Application by Meng Ding, Robert B. Ogle, Jr., Chi Chang, Lei Xue, and Mark Randolph entitled “Memory Cell System Using Silicon-Rich Nitride”. The related application is assigned to Spansion LLC and Advanced Micro Devices, Inc. and is identified by docket number AF01766.

This application also contains subject matter related to a concurrently filed U.S. Patent Application by Amol Joshi, Meng Ding, and Takashi Orimoto entitled “Memory Cell System With Nitride Charge Isolation”. The related application is assigned to Spansion LLC and Advanced Micro Devices, Inc. and is identified by docket number AFJ02039.

### TECHNICAL FIELD

The present invention relates generally to memory system and more particularly to non-volatile memory system.

### BACKGROUND ART

Modern electronics, such as smart phones, personal digital assistants, location based services devices, digital cameras, music players, servers, and storage arrays, are packing more integrated circuits into an ever shrinking physical space with expectations for decreasing cost. One cornerstone for electronics to continue proliferation into everyday life is the non-volatile storage of information such as cellular phone numbers, digital pictures, or music files. In addition to cost and size demands, electronics require improved performance both during use as well as while in storage. Numerous technologies have been developed to meet these requirements.

Various types of non-volatile memories have been developed including electrically erasable programmable read only memory (EEPROM) and electrically programmable read only memory (EPROM). Each type of memory had advantages and disadvantages. EEPROM can be easily erased without extra exterior equipment but with reduced data storage density, lower speed, and higher cost. EPROM, in contrast, is less expensive and has greater density but lacks erasability.

A newer type of memory called “Flash” EEPROM, or Flash memory, has become popular because it combines the advantages of the high density and low cost of EPROM with the electrical erasability of EEPROM. Flash memory can be rewritten and can hold its contents without power. Contemporary Flash memories are designed in a floating gate or a charge trapping architecture. Each architecture has its advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored information may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture which results in decrease in data retention.

The charge trapping architecture offers improved scalability to new semiconductor processes compared to the floating gate architecture. One implementation of the charge trapping architecture is a silicon-oxide-nitride-oxide semiconductor (SONOS) where the charge is trapped in the nitride layer. Leakage and charge-trapping efficiency are two major parameters considered in device performance evaluation. Charge-trapping efficiency determines if the memory devices can keep enough charges in the storage nodes after program/erase operation and is reflected in retention characteristics. It is especially critical when the leakage behavior of storage devices is inevitable. Silicon content in the nitride layer improves the programming and erasing performances but offers poor data retention. Although silicon content plays an important role in charge-trapping efficiency, it does not have same constructive effect on leakage characteristics.

Thus, a need still remains for a memory cell system providing low cost manufacturing, improved yields, improved programming performance, and improved data retention of memory in a system. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a memory cell system including forming a first insulator layer over a semiconductor substrate, forming a charge trap layer having a gradient of a silicon above and below the charge trap layer over the first insulator layer, and forming a second insulator layer over the charge trap layer.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional isometric view of a memory cell system in an embodiment of the present invention;

FIG. 2 is a more detailed cross-sectional view of a memory cell stack in an embodiment of the present invention;

FIG. 3 is a more detailed cross-sectional view of the memory cell stack of FIG. 2 in a formation phase of the first insulator layer;

FIG. 4 is a cross-sectional view of the structure of FIG. 3 in a formation phase of the first intermediate region;

FIG. 5 is a cross-sectional view of the structure of FIG. 4 in a formation phase of the charge trap layer;

FIG. 6 is a cross-sectional view of the structure of FIG. 5 in a formation phase of the second intermediate region;

FIG. 7 is a cross-sectional view of the structure of FIG. 6 in a formation phase of the second insulator layer;

FIG. 8 is a plan view of a portion of a memory array system in an embodiment of the present invention;

FIG. 9 is a plan view of a device in an embodiment of the present invention;

FIG. 10 are electronics systems in an embodiment of the present invention; and

FIG. 11 is a flow chart of a system for a memory cell in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure.

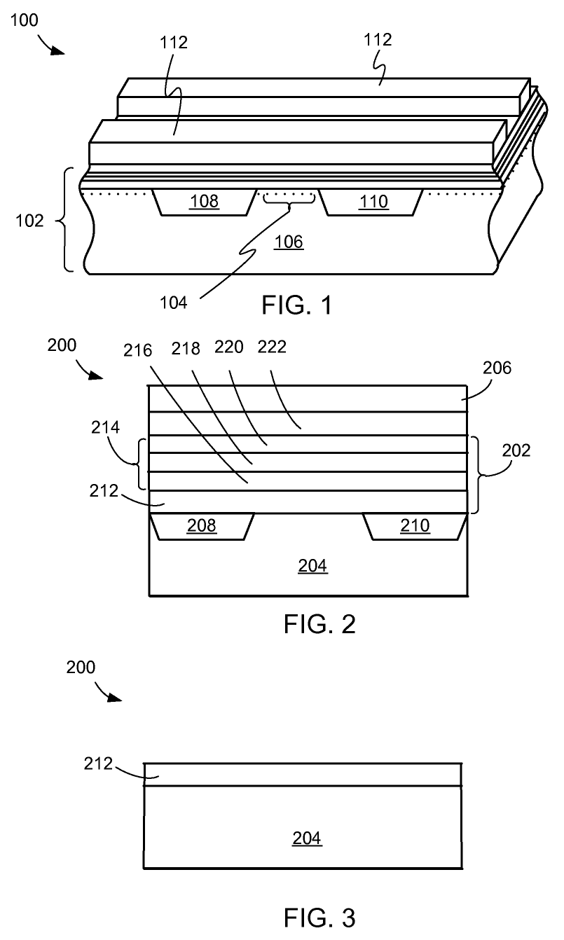

Referring now to FIG. 1, therein is shown a cross-sectional isometric view of a memory cell system 100 in an embodiment of the present invention. The memory cell system 100 includes a memory cell stack 102 including a charge storage region 104 for storing an electrical charge, such as electrons. For illustrative purposes, the memory cell system 100 is shown having one of the charge storage region 104 for storing electrical charges, although it is understood that any number of the charge storage regions maybe provided, as well. It is also understood that the charge storage region 104 may provide storage for any number of electrical charges.

The memory cell stack 102 also includes a semiconductor substrate 106, such as a p-type substrate, having a first region 108, such as an n-type region, and a second region 110, such as an n-type region. The first region 108 may be a source and the second region 110 may be the drain or vice versa. Depending the overall memory array connection with the memory cell system 100, the first region 108, the second region 110, or both may connect to bit lines providing access in to the memory cell system 100 for decoding processes, such as reading, programming and erasing. The memory cell system 100 also includes word lines 112, such as polysilicon, n-type polysilicon, or metal, acting as control gates in cooperation with the bit lines for the decoding processes, such as reading, programming and erasing. Depending upon a signal on the word lines 112 and the connection of the bit lines to an electrical source or drain, the memory cell system 100 may read, program or erase the charge storage region 104.

Referring now to FIG. 2, therein is shown a cross-sectional view of a memory cell stack 200 in an embodiment of the present invention. The memory cell stack 200 may represent the memory cell stack 102 of FIG. 1. The memory cell stack 200 includes a charge-storage stack 202 on a semiconductor substrate 204, such as a p-type silicon substrate. A semiconductor gate 206, such as a polysilicon, n-type polysilicon, or metal gate, is on the charge-storage stack 202.

The charge-storage stack 202 provides a region between a first region 208, such as an n-type region, and a second region 210, such as an n-type region, for storage of electrical charges. The semiconductor substrate 204 and the semiconductor gate 206 provide access for reading and erasing storage locations of the electrical charges.

The charge-storage stack 202 has multiple layers. A first insulator layer 212, such as a dielectric layer of silicon dioxide (SiO₂), of the charge-storage stack 202 is over the semiconductor substrate 204. A charge-storage tri-layer 214 of the charge-storage stack 202 is on the first insulator layer 212. A second insulator layer 222, such as a dielectric layer of silicon dioxide (SiO₂), of the charge-storage stack 202 is on the charge-storage tri-layer 214.

The charge-storage tri-layer 214 provides regions for storage of the electrical charges. The charge-storage tri-layer 214 includes a first intermediate region 216, a charge trap layer 218, and a second intermediate region 220.

The first intermediate region 216 is a region of less silicon rich nitride with a gradient concentration of silicon. The concentration of atomic silicon (Si) closest to the first insulator layer 212 can be as low as 42.9% similar to regular silicon nitride (SiN) concentration. The silicon concentration increases in the first intermediate region 216 with the largest silicon concentration next to the charge trap layer 218. The charge trap layer 218 primarily provides the charge storage traps or sites and may be a silicon rich nitride (SRN or SiRN) layer of silicon nitride (Si_{X}N_{Y}) or a silicon layer without nitride.

The second intermediate region 220 is a region of less silicon rich nitride with a gradient concentration of silicon. The concentration of atomic silicon (Si) closest to the second insulator layer 222 can be as low as 42.9% similar to regular silicon nitride (SiN) concentration. The silicon concentration increases in the second intermediate region 220 with the largest silicon concentration next to the charge trap layer 218.

The gradient in the first intermediate region 216 and the second intermediate region 220 may be a continuous change in concentration from the first insulator layer 212 and the second insulator layer 222, respectively, to the charge trap layer 218. The gradient in the first intermediate region 216 and the second intermediate region 220 may be formed through multiple stratified thin layers of different silicon concentration.

For illustrative purposes, the gradient in the first intermediate region 216 and the second intermediate region 220 are described as substantially same, although it is understood that the gradient in the first intermediate region 216 and the gradient in the second intermediate region 220 may differ. Also for illustrative purpose, the first intermediate region 216 is described is as between the first insulator layer 212 and the charge trap layer 218, although it is understood that the first intermediate region 216 may also provide charge trap sites. Further for illustrative purposes, the second intermediate region 220 is described is as between the second insulator layer 222 and the charge trap layer 218, although it is understood that the second intermediate region 220 may also provide charge trap sites.

For the memory cell system 100 of FIG. 1, leakage and charge-trapping efficiency are two major parameters considered in memory system (not shown) performance evaluation. Charge-trapping efficiency determines if the memory devices can keep enough charges in the charge-storage tri-layer 214 after program/erase operation and is reflected in retention characteristics.

The charge-trapping efficiency is proportional to relative silicon content ratio in nitride layer or the use of a silicon layer without nitride. The increased silicon content improves electron mobility in the charge trap layer 218. Although silicon content plays an important role in charge-trapping efficiency, it does not have same constructive effect on leakage characteristics. Gate oxide scaling in new semiconductor processes reduces the thickness of the gate oxide to increase the direct tunneling current leading to excessive gate leakage when charge is stored in the charge-storage tri-layer 214.

It has been discovered that the charge-storage tri-layer 214 reduces leakage current through the first insulator layer 212 and the second insulator layer 222 to improve data retention while providing flexibility to tune the charge trap layer 218 to a predetermined erase and program performance. The charge-storage tri-layer 214 includes the first intermediate region 216 and the second intermediate region 220 below and above, respectively, the charge trap layer 218. The aim of the second insulator layer 222 is not only to inhibit gate injection, but also to block the charges injected from the silicon at the top oxide-nitride interface, resulting in a higher trapping efficiency. Oxygen rich layer is obtained at the nitride-top oxide interface due to the oxidation of the second intermediate region 220. This results in a larger memory window in spite of the decreased nitride thickness because charge escapes to the gaet is reduced during programming. If pinholes are present in the thinner nitride layer, they can be filled with oxide during oxidation. Similarly, the first intermediate region 216 along with the first insulator layer 212 reduces the leakage current from the charge trap layer 218 back to the semiconductor substrate 204. With data retention improved, the silicon content in the charge trap layer 218 may be adjusted to improve the erase and program performance compared to silicon rich nitride or nitride alone.

Referring now to FIG. 3, therein is shown a more detailed cross-sectional view of the memory cell stack 200 of FIG. 2 in a formation phase of the first insulator layer 212. This more detailed cross-sectional view depicts the memory cell stack 200 between the first region 208 of FIG. 2 and the second region 210 of FIG. 2. The first insulator layer 212 is formed on the semiconductor substrate 204. The first insulator layer 212 may be formed by any number of processes, such as thermal oxidation.

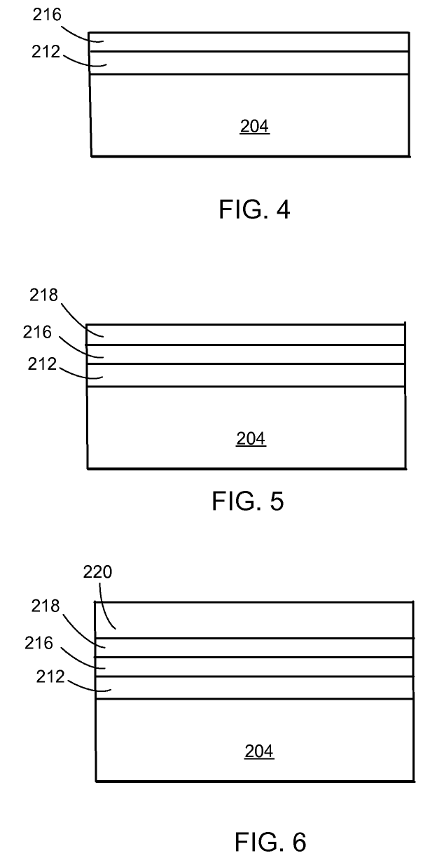

Referring now to FIG. 4, therein is shown a cross-sectional view of the structure of FIG. 3 in a formation phase of the first intermediate region 216. The first intermediate region 216 is formed on the first insulator layer 212 and over the semiconductor substrate 204. The first intermediate region 216 may be formed by any number of processes, such as an atomic layer deposition (ALD). The silicon to nitride ratio is increased at a predetermined rate where the silicon concentration closest to the first insulator layer 212 is less than the silicon concentration closest to the charge trap layer 218 of FIG. 2.

The silicon-rich nitride may be formed by an atomic layer deposition process (ALD) wherein two types of gases, such as NH₃ and DCS (SiH₄Cl₂), interact during the deposition of the silicon-rich nitride. A ratio of the gases, such as NH₃:DCS(SiH₄Cl₂), is below approximately 360:60, but higher than approximately 53:330, to be considered silicon-rich nitride. The silicon-rich nitride may include a higher ratio, such as 28:360, to provide conductivity for single bit storage. A less silicon rich nitride layer closest to the first insulator layer 212 may contain as low as 42.9% silicon content compared to the silicon content of the charge trap layer 218.

Referring now to FIG. 5, therein is shown a cross-sectional view of the structure of FIG. 4 in a formation phase of the charge trap layer 218. The charge trap layer 218 is deposited on the first intermediate region 216 over the first insulator layer 212 and the semiconductor substrate 204. The charge trap layer 218 is continued to be formed along with the first intermediate region 216 using the atomic layer deposition process. The silicon content of the charge trap layer 218 is greater than in the first intermediate region 216 and may be a layer of silicon rich nitride (SiRN) or silicon without nitride.

Referring now to FIG. 6, therein is shown a cross-sectional view of the structure of FIG. 5 in a formation phase of the second intermediate region 220. The second intermediate region 220 is continued to be formed along with the charge trap layer 218 using the atomic layer deposition process. The silicon to nitride ratio is decreased at a predetermined rate where the silicon concentration closest to the second insulator layer 222 of FIG. 2 is less than the silicon concentration closest to the charge trap layer 218. A less silicon rich nitride layer closest to the second insulator layer 222 may contain as low as 42.9% silicon content compared to the silicon content of the charge trap layer 218.

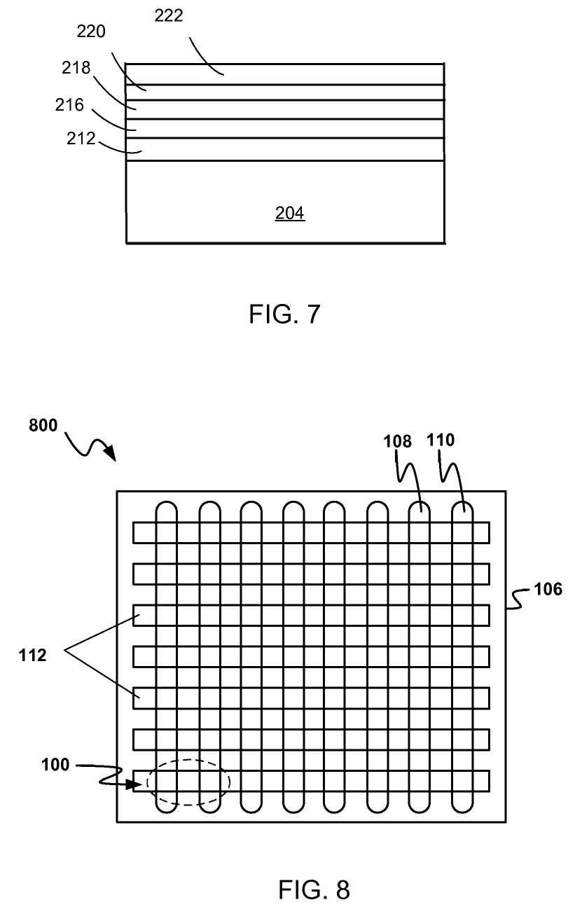

Referring now to FIG. 7, therein is shown a cross-sectional view of the structure of FIG. 6 in a formation phase of the second insulator layer 222. The second intermediate region 220 from FIG. 5 undergoes thermal oxidation, such as steam oxidation or high temperature oxidation (HTO) deposition, to form the second insulator layer 222, as the top blocking oxide layer, from the upper portion of the nitride, regular silicon nitride, or less rich silicon nitride layer from FIG. 5.

The thermal oxidation of the nitride is at the expense of the nitride thickness of the second intermediate region 220. Any pinholes present in the nitride/regular silicon nitride layer can be filled with oxide during oxidation of the nitride. The oxidation process forms a better interface between the second insulator layer 222 and the second intermediate region 220 improving the quality and reliability of the memory cell stack 200 of FIG. 2. The resultant thickness of the charge trap layer 218 is in the range of 30 to 80 angstrom and the second intermediate region 220 is in the range of 0 to 60 angstrom both over the semiconductor substrate 204. The oxidation process may oxidize the entire thickness of the second intermediate region 220. The structure of the second intermediate region 220 remains but with a different composition resulting from the oxidation.

Referring now to FIG. 8, therein is shown a plan view of a portion of a memory system 800 in an embodiment of the present invention. The memory system 800 is an M×N array of memory cell systems 100. The semiconductor substrate 106 has a plurality of first regions 108 and second regions 110 as implanted bit lines extending in parallel with a plurality of the word lines 112 extending in parallel and at right angles to the plurality of implanted bit lines. The word lines 112 and bit lines have contacts and interconnections (not shown) to the programming circuitry to be discussed further in FIG. 8.

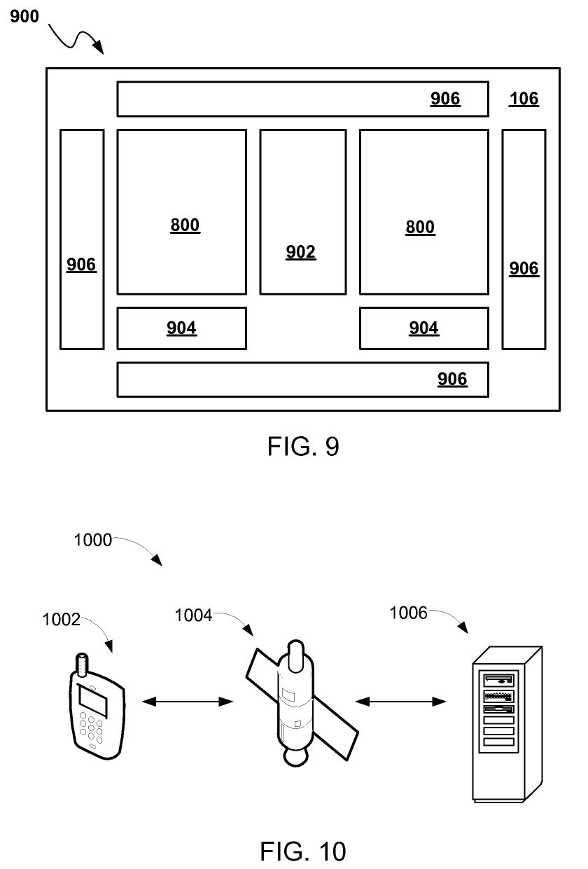

Referring now to FIG. 9, therein is shown a plan view of a device 900 in an embodiment of the present invention. The device 900 is a semiconductor device including the memory system 800 as well as the memory cell system 100. The device 900 commonly includes the semiconductor substrate 106 in which one or more high-density core regions and one or more low-density peripheral portions are formed.

High-density core regions typically include one or more memory systems 800 of individually addressable, substantially identical memory cell systems 100 of FIG. 1. Low-density peripheral portions typically include input/output (I/O) circuitry and programming circuitry for individually and selectively addressing the memory cell system 100. The programming circuitry is represented in part by and includes one or more x-decoders 902 and y-decoders 904, cooperating with I/O circuitry 906 for connecting the source, gate, and drain of selected addressed memory cells to predetermined voltages or impedances to effect designated operations on the memory cell, e.g., programming, reading, and erasing, and deriving necessary voltages to effect such operations.

For illustrative purposes, the device 900 is shown as a memory device, although it is understood that the device 900 may other semiconductor devices having other functional blocks, such as a digital logic block, a processor, or other types of memories. Also for illustrative purposes, the device 900 is described as a single type of semiconductor device, although it is understood that the device 900 may be a multichip module utilizing the present invention with other types of devices of similar or different semiconductor technologies, such as power devices or microelectromechanical systems (MEMS). Further for illustrative purposes, the device 900 is described as a semiconductor device, although it is understood that the device 900 may be a board level product including the present invention.

Referring now to FIG. 10, therein is shown electronic systems 1000 in an embodiment of the present invention. A smart phone 1002, a satellite 1004, and a compute system 1006 are examples of the electronic systems 1000 using the present invention. The electronic systems 1000 may be any system that performs any function for the creation, transportation, storage, and consumption of information. For example, the smart phone 1002 may create information by transmitting voice to the satellite 1004. The satellite 1004 is used to transport the information to the compute system 1006. The compute system 1006 may be used to store the information. The smart phone 1002 may also consume information sent from the satellite 1004.

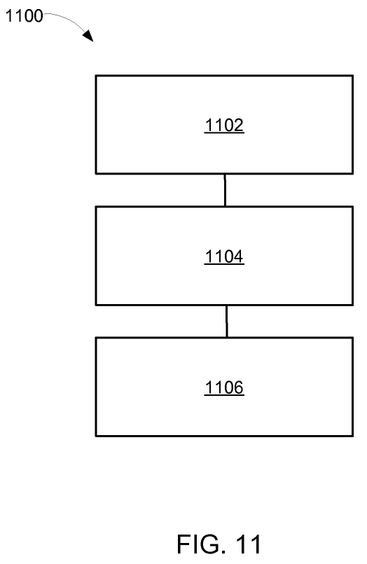

Referring now to FIG. 11, therein is shown a flow chart of a system 1100 for a memory cell system 100 in an embodiment of the present invention. The system 1100 includes forming a first insulator layer over a semiconductor substrate in a block 1102; forming a charge trap layer having a gradient of a silicon above and below the charge trap layer over the first insulator layer in a block 1104; and forming a second insulator layer over the charge trap layer in a block 1106.

It has been discovered that the present invention thus has numerous aspects.

It has been discovered that the charge-storage tri-layer 214 reduces leakage current through the first insulator layer 212 and the second insulator layer 222 to improve data retention while providing flexibility to tune the charge trap layer 218 to a predetermined erase and program performance. The atomic layer deposition process allows control of the silicon content variation along the gradient to reduce charge loss but control the thickness of the overall memory stack.

An aspect is that the present invention is that the tri-layer of a first intermediate region and a second intermediate region next to the bottom tunneling oxide layer and the top blocking oxide layer, respectively, with the charge trap layer in the middle improves the data retention compared to a silicon rich nitride layer alone. The first intermediate region and the second intermediate region reduce leakage current through the bottom tunneling oxide layer and the top blocking oxide layer, respectively, resulting in a higher trapping efficiency.

Another aspect of the present invention is that the silicon content may be adjusted in the charge trap layer to improve the erase and program performance.

Yet another aspect of the present invention is that the oxidation process of the second intermediate region to form the top blocking oxide layer provides large oxygen-related electron trap densities obtained at the nitride-top oxide interface due to the oxidation of the nitride. This results in a larger memory window in spite of the decreased nitride thickness. If pinholes are present in the second intermediate region, they can be filled with oxide during oxidation of the nitride. The retention and degradation behavior are improved.

Yet another aspect of the present invention is that the second intermediate region protects the charge trap sites in the silicon rich layer from steam oxidation process.

Yet another aspect of the present invention is that the charge trap layer may tune the silicon content to balance erase and program performance with the data retention.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the memory cell system method and apparatus of the present invention furnish important and heretofore unknown and unavailable solutions, capabilities, and functional aspects for memory systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A memory cell manufacturing method comprising:
forming a first insulator layer over a semiconductor substrate;
forming a charge trap layer having a gradient of a silicon above and below the charge trap layer over the first insulator layer; and
forming a second insulator layer over the charge trap layer.

2. The manufacturing method as claimed in claim 1 wherein forming the charge trap layer having a gradient of the silicon above and below the charge trap layer includes:
forming a first intermediate region having the gradient for reduction of charge mobility below the charge trap layer; and
forming a second intermediate region having the gradient for reduction of charge mobility above the charge trap layer.

3. The manufacturing method as claimed in claim 1 wherein forming the charge trap layer having the gradient of the silicon above and below includes forming a region in the gradient with a nitride gradient above the charge trap layer.

4. The manufacturing method as claimed in claim 1 wherein forming the charge trap layer having the gradient of the silicon above and below includes forming a region in the gradient with a nitride gradient below the charge trap layer.

5. The manufacturing method as claimed in claim 1 further comprising:
forming a memory system with memory cell systems; and
forming a device or an electronic system with the memory system.

6. A memory cell manufacturing method comprising:
forming a first dielectric layer over a semiconductor substrate;
forming a silicon layer having a gradient of a nitride above and below the silicon layer over the first dielectric layer; and
oxidizing a second dielectric layer over the silicon layer.

7. The manufacturing method as claimed in claim 6 wherein forming the silicon layer having the gradient of the nitride above and below the silicon layer includes:
forming a first nitride gradient region with a greatest nitride concentration next to the first dielectric layer; and
forming a second nitride gradient with a greatest nitride concentration next to the second dielectric layer.

8. The manufacturing method as claimed in claim 6 wherein forming the silicon layer includes forming a nitride in the silicon layer.

9. The manufacturing method as claimed in claim 6 wherein forming the first dielectric layer includes forming an oxide layer.

10. The manufacturing method as claimed in claim 6 further comprising connecting a gate contact over the second dielectric layer.

11. A memory cell system comprising:
a first insulator layer over a semiconductor substrate;
a charge trap layer having a gradient of a silicon above and below the charge trap layer over the first insulator layer; and
a second insulator layer over the charge trap layer.

12. The system as claimed in claim 11 wherein the charge trap layer having a gradient of the silicon above and below the charge trap layer includes:
a first intermediate region having the gradient for reduction of charge mobility below the charge trap layer; and
a second intermediate region having the gradient for reduction of charge mobility above the charge trap layer.

13. The system as claimed in claim 11 wherein the charge trap layer having the gradient of the silicon above and below includes a region in the gradient with a nitride gradient above the charge trap layer.

14. The system as claimed in claim 11 wherein the charge trap layer having the gradient of the silicon above and below includes a region in the gradient with a nitride gradient below the charge trap layer.

15. The system as claimed in claim 11 further comprising:
a memory system with memory cell systems; and
a device or an electronic system with the memory system.

16. The system as claimed in claim 11 wherein:
the first insulator layer is a first dielectric layer over the semiconductor substrate;
the charge trap layer is a silicon layer having a gradient of the silicon above and below the charge trap layer over the first insulator layer;
the second insulator layer is a second dielectric layer over the charge trap layer.

17. The system as claimed in claim 16 wherein the silicon layer having the gradient of the silicon above and below the silicon layer includes:
a first nitride gradient region with a greatest nitride concentration next to the first dielectric layer; and
a second nitride gradient with a greatest nitride concentration next to the second dielectric layer.

18. The system as claimed in claim 16 wherein the silicon layer includes a nitride.

19. The system as claimed in claim 16 wherein the first dielectric layer is an oxide layer.

20. The system as claimed in claim 16 further comprising a gate contact over the second dielectric layer.
